(19) United States
(12) Patent Application Publication
(10) Pub. No.: US 2008/0157243 A1
(43) Pub. Date: Jul. 3, 2008

(54) Image Sensor and Method for Manufacturing the Same

(76) Inventor: EUN SANG CHO, Yongin-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/842,696

(22) Filed: Aug. 21, 2007

(30) Foreign Application Priority Data
Dec. 27, 2006 (KR) 10-2006-0135712
Dec. 29, 2006 (KR) 10-2006-0138960

(51) Int. Cl. H01L 31/0232; H01L 21/00

(52) U.S. Cl. 257/432; 438/70; 257/E31.001

(57) ABSTRACT

Embodiments of an image sensor and method of manufacturing the same are provided. An image sensor can include an interlayer dielectric layer formed on a substrate including a photodiode; a color filter layer formed on the interlayer dielectric layer; a first oxide film microlens formed on the color filter layer; and a second oxide film microlens formed on the first oxide film microlens.

### CROSS-REFERENCE TO RELATED APPLICATIONS

The present application claims the benefit under 35 U.S.C. §119 of Korean Patent Application No. 10-2006-0135712, filed Dec. 27, 2006 and Korean Patent Application No. 10-2006-0138960, filed Dec. 29, 2006, which are hereby incorporated by reference in their entirety.

### BACKGROUND

In order to improve light sensitivity of an image sensor, typically either a technology increasing a fill factor of area occupied by a photodiode among the overall area of an image sensor, or focusing light onto the photodiode by changing a path of light incident on regions other than the photodiode have been used.

A representative example of a focusing technology is to form a microlens.

According to the related art, a method for forming a microlens during a process for manufacturing an image sensor has generally used a scheme of performing a micro photo process using a special photoresist for the microlens and then performing a reflowing process.

However, according to the related art, since the loss amount of the photoresist becomes large upon reflowing the photoresist, there is a gap (G) between microlenses so that the amount of light incident on the photodiode is reduced, which may result in a faulty image.

In addition, because the special photoresist for the microlens is expensive as compared to a general photoresist, the cost of the manufacturing process is increased.

Further, since it is difficult to standardize a reflowing process, a photoresist sensitively responds during the reflowing process. Therefore, it is possible to non-uniformly form the shape of the microlens.

In addition, in the related art because the microlens is exposed to the outside, the microlens can be damaged by friction, etc.

Moreover, cross-talk can occur when a gap between the microlenses is wide.

### BRIEF SUMMARY

Embodiments of the present invention provide an image sensor and a method for manufacturing the same capable of minimizing a gap (G) between microlenses.

An embodiment provides an image sensor and a method for manufacturing the same capable of reducing cost in manufacturing process by forming microlens without adopting a special photoresist for the microlens.

An embodiment provides a method for manufacturing an image sensor capable of relatively uniformly processing a shape of a microlens in an image sensor. Accordingly, all microlenses on a chip can be formed to have the same curvature.

An embodiment provides a method for manufacturing an image sensor including a microlens with durability against friction from the outside.

An embodiment provides a method for manufacturing an image sensor capable of reducing the possibility of cross-talk generation by reducing a gap between microlenses.

An image sensor according to an embodiment can include: an interlayer dielectric layer formed on a substrate including a photodiode; a color filter layer formed on the interlayer dielectric layer; a first oxide film microlens formed on the color filter layer while having a constant curvature; and a second oxide film microlens formed on the first oxide film microlens.

A method for manufacturing an image sensor according to an embodiment can include: forming an interlayer dielectric layer on a substrate including a photodiode; forming a color filter layer on the interlayer dielectric layer; forming an oxide film on the color filter layer; forming a plurality of photoresist patterns with a predetermined gap on the oxide film; and forming a first oxide film microlens with a constant curvature by etching the oxide film using the photoresist pattern as a mask.

A method for manufacturing an image sensor according to an embodiment can include: forming a microlens on a substrate; and forming a transparent film having greater hardness than the material of the microlens on the microlens.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross-sectional view of an image sensor according to an embodiment;

FIGS. 2 to 4 are cross-sectional views for illustrating a method for manufacturing an image sensor according to an embodiment;

FIG. 5 is a cross-sectional view of an image sensor according to an embodiment; and

FIGS. 6 and 7 are cross-sectional views for illustrating a method for manufacturing an image sensor according to an embodiment.

### DETAILED DESCRIPTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a semiconductor device and a method for manufacturing the same according to embodiments will be described with reference to the accompanying drawings.

With reference to the description of the embodiments, when a layer is described as being formed “on/under” another layer, the “on/under” includes “what is directly formed” or “what is formed by interposing other layers therebetween”.

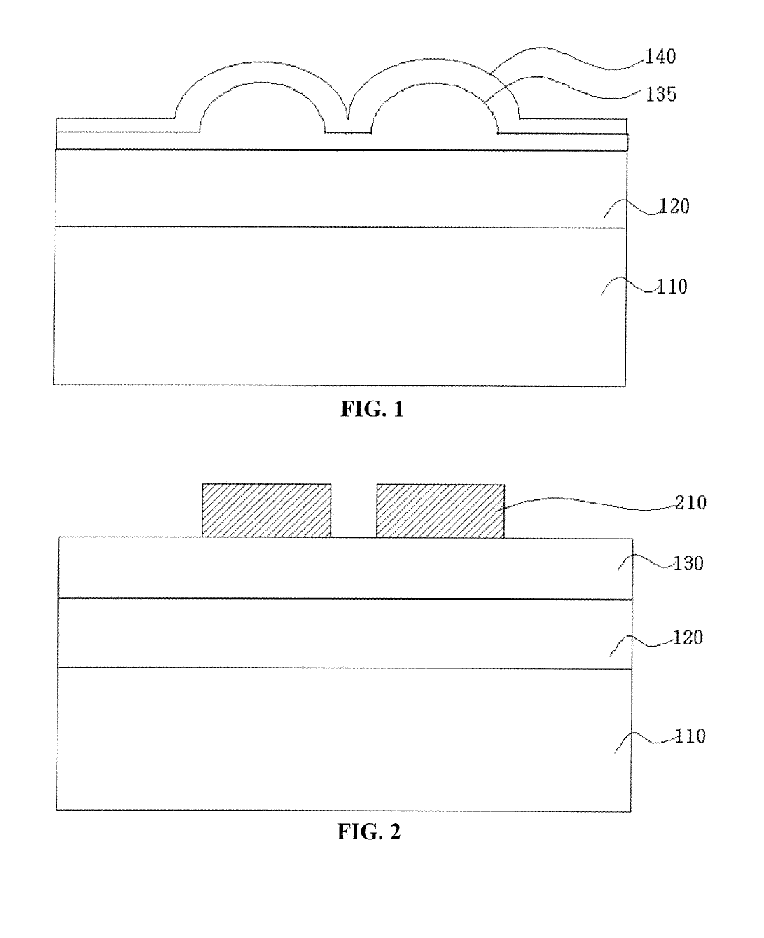

FIG. 1 is a cross-sectional view of an image sensor according to a first embodiment.

Referring to FIG. 1, image sensor according to an embodiment can include: an interlayer dielectric layer 110 formed on a substrate (not shown); a color filter layer 120 formed on the interlayer dielectric layer 110; a first oxide film microlens 135 formed on the color filter layer 120 while having a same curvature for all microlenses; and a second oxide film microlens 140 formed on the first oxide film microlens 135.

The first oxide film microlens 135 can inhibit exposure of a layer below the first oxide film microlens 135.

This is to inhibit or prevent an attack by an etching process for forming the first oxide film microlens 135 because the layer below the first oxide film microlens 135 may be a color filter layer 120 or a planarization layer (not shown), and such layers may be formed of a polymer or a photoresist.

At this time, the second oxide film microlens 140 can constantly maintain refractive index by using the same material as the material for forming the first oxide film microlens 135.

The second oxide film microlens 140 can be formed on the first oxide film microlens 135 so as not to expose the first oxide film microlens 135 while maintaining a same curvature for all microlenses.

The image sensor according to the first embodiment can be formed of the first oxide film microlens and the second oxide film microlens so that a gap between the microlenses is reduced to a level of zero gap, making it possible to improve the image quality of the image sensor.

Also, according to the first embodiment, the microlens formed of the oxide film can have a constant curvature, meaning all microlenses can have the same curvature.

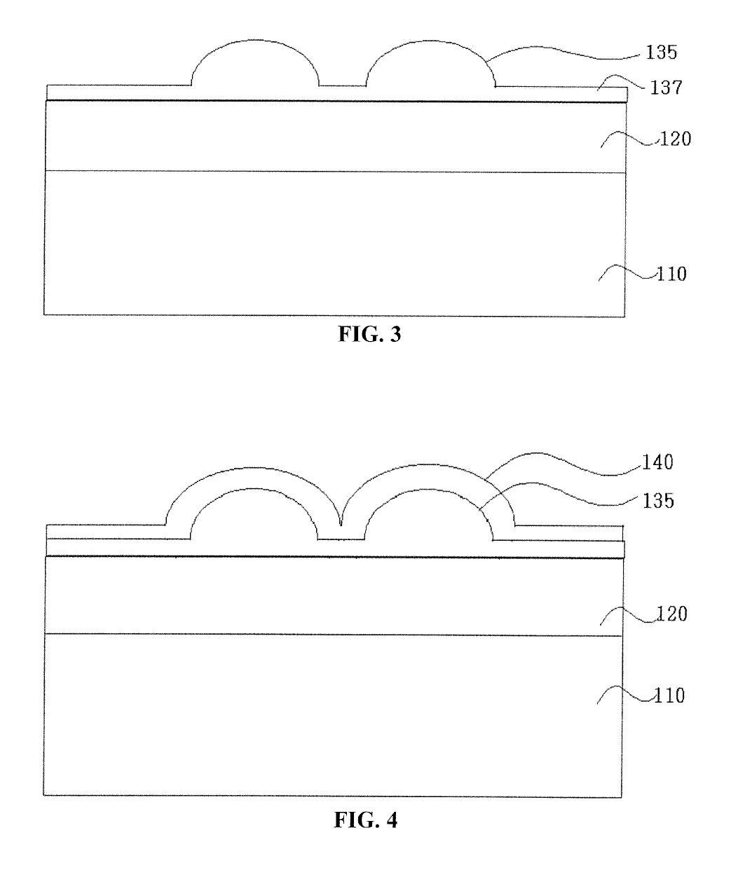

Hereinafter, a method for manufacturing an image sensor according to the first embodiment will be described with reference to FIGS. 2 to 4.

Referring to FIG. 2, an interlayer dielectric layer 110 can be formed on a substrate (not shown) including a photodiode (not shown).

The interlayer dielectric layer 100 can be formed in a multi-layer. Although not shown, after one interlayer dielectric layer is formed, a light-shielding layer for preventing light from being incident on portions other than a photodiode region can be formed and another interlayer dielectric layer can be formed on the light-shielding layer.

Subsequently, a protection film (not shown) for protecting devices from moisture and scratch can further be formed on the interlayer insulation layer 110.

Color filter layers 120 can be formed on the protection layer providing, for example red (R), green (G), and blue (B) color filters for filtering light by wavelength range by applying a dyeable resist and then performing exposure and developing processes.

In a further embodiment, a planarization layer (PL) (not shown) can be formed on the color filter layer 120 in order to secure flatness for forming a focal length adjusting lens layer.

Next, an oxide film 130 can be formed on the color filter layer 120.

The oxide film 130 can be a low temperature oxide film deposited at a temperature of about 200° C. or less. The oxide film 130 can be SiO₂. At this time, the oxide film 130 can be formed, for example, by means of a chemical vapor deposition or (CVD) a plasma enhanced CVD (PECVD).

Subsequently, a plurality of photoresist patterns with a predetermined gap can be formed on the oxide film 130.

In contrast to the related art, the photoresist pattern 210 can use a general photoresist, which is not a special photoresist for a microlens. Not using a special photoresist for a microlens can reduce manufacturing cost. For example, the photoresist pattern 210 can be formed using a KrF photoresist (PR).

In a specific embodiment, the photoresist pattern 210 can use a general photoresist, not a special photoresist for a microlens, so that it can perform a subsequent process without performing a separate reflowing process. This can make it possible to reduce manufacturing cost.

Also, the thickness of the oxide film formed on the color filter layer 120 can be formed substantially identical with the thickness of the photoresist 210 formed on the oxide film so that in a subsequently performed process of forming the first oxide film microlens 135, the first oxide film microlens 135 with a same curvature can be formed.

Referring to FIG. 3, the first oxide film microlens 135 can be formed by etching the oxide film 130 using the photoresist pattern 210 as a mask.

At this time, the etching selection ratios of the photoresist pattern 210 and the oxide film 130 are substantially the same so that the ratios of the photoresist pattern 210 etched and the oxide film 130 etched can be substantially the same, making it possible to form the first oxide film microlens 135 with a same curvature for all microlenses.

In the step of forming the first oxide film microlens 135, the ratio of source power to bias power can be 3˜10:1 so that the ratios of the photoresist pattern 210 etched and the oxide film 130 etched are substantially the same, making it possible to form the first oxide film microlens 135 in a semicircular form.

At this time, the first oxide film microlens 135 can be formed using an etching process condition for making an isotropic etching so that the first oxide film microlens 135 in the semicircular form can be formed.

For example, a step of forming the first oxide film microlens 135 can be performed tinder pressure of about 80˜120 mT, source power of about 300˜700 W, bias power of about 0˜300 W, CF₄ of about 20˜70 sccm, CH₂F₂ of about 5˜25 sccm, O₂ of about 5˜300 sccm, and Ar of about 200˜600 sccm so that the ratios of the photoresist pattern 210 etched and the oxide film 130 etched by means of the isotropic etching are substantially the same, making it possible to form the first oxide film microlens 135 in the semicircular form.

Also, a method for manufacturing the image sensor according to the first embodiment can be characterized in that in forming the first oxide film microlens 135 by etching the oxide film 130, the oxide film 130 is etched to allow the lower side thereof to remain 137 so that the layer 120 below the oxide film 130 is not exposed.

This can inhibit an attack by an etching process for forming the first oxide film microlens 135, since the layer below the first oxide film microlens 135 may be the color filter layer 120 or a planarization layer (not shown), and such layers may be formed of a polymer or a photoresist.

Referring to FIG. 3, there may be a gap between the first oxide film microlenses 135.

In order to remove or reduce the gap, a second oxide film microlens 140 can further be formed on the substrate having the first oxide film microlens 135.

At this time, the second oxide film microlens 140 can constantly maintain refractive index by using the same material as the first oxide film microlens 135.

Referring to FIG. 4, the second oxide film microlens 140 can be formed on the substrate including the first oxide film microlens 135 so that the gap between the microlenses can be reduced to a level of zero gap, making it possible to improve the image quality of the image sensor. In one embodiment, an oxide layer can be deposited on the first oxide film microlens 135 thereby forming the second oxide film microlens 140.

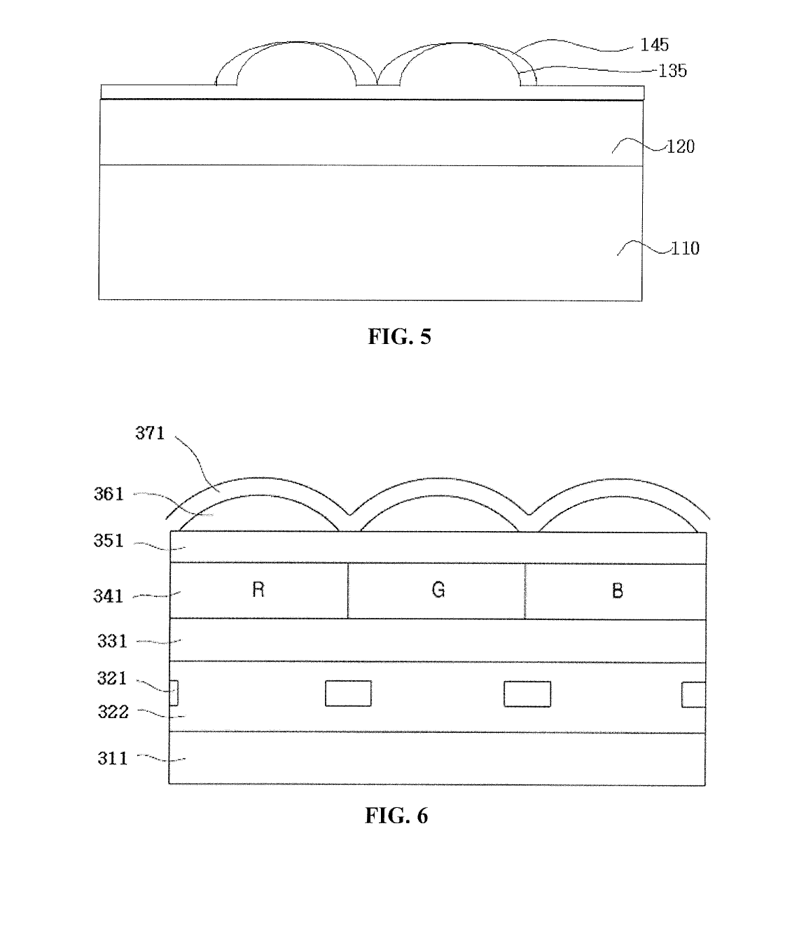

FIG. 5 is a cross-sectional view of an image sensor according to a second embodiment.

The second embodiment can incorporate the features of the first embodiment.

In the embodiment illustrated in FIG. 5, the second oxide film microlens 140 can be etched back after forming the second oxide film microlens 140 to form an oxide film microlens 145 in a spacer form on both sides of the first oxide film microlens 135.

At this time, forming the oxide film microlens 145 in the spacer form can be performed by etching back the second oxide film microlens 140 without having a separate photoresist so that the oxide film microlens 145 in the spacer form can be formed on both sides of the first oxide film microlens 135.

Such an oxide film microlens 145 can be formed so that the gap between the microlenses can further be reduced.

A method for manufacturing the image sensor according to the second embodiment forms the first oxide film microlens and the second oxide film microlens to reduce the gap between the microlenses to a level of zero gap, making it possible to improve the image quality of the image sensor.

In addition, all the microlenses formed of the oxide film can have a constant curvature.

In an embodiment, the oxide film microlens can be formed without adopting a special photoresist for the microlens, making it possible to reduce manufacturing cost.

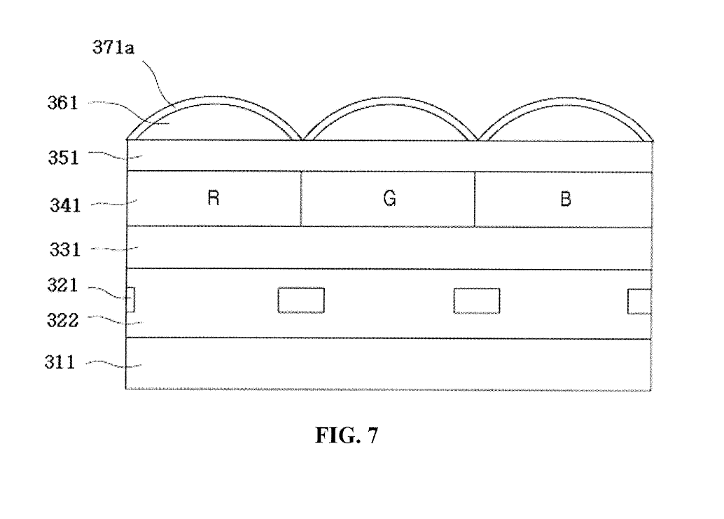

FIG. 6 is a cross-sectional view for illustrating a method for manufacturing an image sensor according to a third embodiment.

Referring to FIG. 6, in an embodiment, a microlens can be produced by means of a reflowing process with respect to a photoresist pattern, instead of the first oxide film microlens described above.

Accordingly, a method for forming a microlens proposed by the third embodiment can be applied to all CMOS image sensors with a basic structure as illustrated by the image sensor shown in FIG. 6.

The third embodiment described below can comprehensively be applied to all kinds of image sensors having a microlens.

As shown in FIG. 6, an image sensor according can be formed by sequentially stacking a photodiode 311, inter-metal dielectric layer 322, a planarization layer 331, a color filter layer 341 formed of R, G, and B color filters, a passivation layer 351, and a microlens 361 on a substrate (not shown). Conductive metal wiring 321 can be formed within the inter-metal dielectric layer 322.

A transparent film 371 having greater hardness than the microlens 361 can be formed on the microlens 361.

In an embodiment, the transparent film 361 can be an oxide film 371, but embodiments are not limited thereto.

In an embodiment, the oxide film 371, can be a SiO₂ layer that can be deposited on the microlens 361 by means of a low temperature CVD process.

At this time, the range of the low temperature can be about 140° C.˜230° C., for example, the range having a deviation of ±20% from 180° C.

Also, when depositing and forming the thin oxide film 371 by means of the low temperature CVD process, a phenomenon can occur where the thickness of the oxide film 371 stacked in a valley region between the microlens 361 is thicker than that of the oxide film 371 stacked in the apex region of the lens 361.

Therefore, in a further embodiment, as illustrated in FIG. 7, etching and trimming processes can be performed to the oxide film 371 by injecting predetermined gas during the low temperature CVD process.

In an embodiment, C₅F₈, O₂, CF₄, and Ar can be mixed and injected at predetermined ratio, to perform a trimming process of the thickness of the oxide film 371.

A mixing ratio of C₅F₈, O₂, CF₄, and Ar can be 1: 1.1˜3: 11˜3: 50˜60.

An example of an etching condition with respect to the etching process can be performed as follows.

| | |
|---|---|
| Chamber Top [W] | 1200 |
| Chamber Bottom [W] | 600 |
| C₅F₈ [sccm] | 10 |
| O₂ [sccm] | 12 |
| CF₄ [sccm] | 120 |
| Ar [sccm] | 550 |

Referring to FIG. 7, an oxide film microlens 371a in a convex lens shape can be formed of the material forming the SiO₂ layer. The microlens can be formed so that there is no gap between neighboring lenses.

It can be appreciated that the thickness of the oxide film stacked in the valley corresponding between the microlenses 361 is relatively thinner than that in the case where the oxide film is not stacked in the valley. That is, it can be found that the thickness of the oxide film 371a formed on the microlens 361 is uniformly formed as a whole.

Also, it can be appreciated that the gap between the microlenses can be reduced by means of the oxide film 371a. As a result, the possibility of cross-talk generation can be considerably reduced. According to an experiment using the etching conditions described in the table above, the gap between the microlenses can be reduced to 60 nm or less.

Also, since the oxide film, which is a material making the hardness of the photoresist high, can be deposited on the microlens, it can be expected that resistance against moisture and friction from the outside can be increased.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a plurality of first oxide film microlenses formed on a substrate; and
a second oxide film microlens formed on each first oxide film microlens, wherein the second oxide microlens is formed in a spacer form at sides of each first oxide film microlens.

2. The image sensor according to claim 1, wherein a lower portion of a material of the plurality of first oxide film microlenses remains on the substrate.

3. The image sensor according to claim 1, wherein each of the second oxide film microlenses have substantially the same curvature, and wherein each of the first oxide film microlenses have substantially the same curvature.

4. The image sensor according to claim 1, wherein the plurality of first microlenses is formed of the same material as the second microlens.

5. A method for manufacturing an image sensor, comprising:
forming a plurality of first microlenses on a substrate; and
depositing a transparent film on the plurality of first microlenses; and
etching the transparent film to provide a zero-gap between each of the plurality of first microlenses.

6. The method according to claim 5, wherein the transparent film comprises an oxide layer.

7. The method according to claim 5, wherein forming the plurality of first microlenses on the substrate comprises:
forming an oxide film on the substrate;
forming a plurality of photoresist patterns with a predetermined gap on the oxide film; and
etching the oxide film using the plurality of photoresist patterns as a mask to form a plurality of first oxide film microlenses each having substantially the same curvature.

8. The method according to claim 7, wherein the plurality of photoresist patterns comprise a general photoresist, not a special microlens photoresist.

9. The method according to claim 7, wherein forming the plurality of photoresist patterns does not comprise a separate reflowing process.

10. The method according to claim 7, wherein the thickness of the oxide film formed on the substrate is substantially the same as the thickness of the photoresist patterns formed on the oxide film.

11. The method according to claim 7, wherein the etching selection ratios of the plurality of photoresist patterns and the oxide film are substantially the same.

12. The method according to claim 7, wherein etching the oxide film using the plurality of photoresist patterns as a mask comprises etching the oxide film such that a lower portion of the oxide film remains on the substrate.

13. The method according to claim 7, wherein etching the oxide film comprises performing isotropic etching.

14. The method according to claim 7, wherein during etching of the oxide film, the ratio of source power to bias power is 3˜10:1.

15. The method according to claim 5, wherein etching the transparent film is performed until the first microlenses are exposed such that a spacer is formed at sides of each of the plurality of first microlenses.

16. The method according to claim 15, wherein forming the spacer form does not use a photoresist pattern.

17. The method according to claim 5, wherein the transparent film has a greater hardness than the material of the plurality of first microlenses.

18. The method according to claim 5, wherein depositing the transparent film comprises forming a SiO₂ layer by performing a low temperature CVD process.

19. The method according to claim 5, further comprising etching the transparent film to have a microlens shape on each of the plurality of first microlenses by injecting a mixing gas formed of C₅F₈, O₂, CF₄, and Ar.

20. The method according to claim 19, wherein a mixing ratio of C₅F₈, O₂, CF₄, and Ar is 1: 1.1˜3: 11˜3: 50˜60.
